(19) United States
(12) Patent Application Publication
(10) Pub. No.: US 2026/0053004 A1
(43) Pub. Date: Feb. 19, 2026

(54) NOVEL INTERPOSER FORMATION METHOD USING SACRIFICIAL LAYER REMOVAL

(71) Applicant: Taiwan Semiconductor Manufacturing Company, Ltd., Hsinchu (TW)

(72) Inventor: Hung-Te LIN, Hsinchu County (TW)

(73) Assignee: Taiwan Semiconductor Manufacturing Company, Ltd., Hsinchu (TW)

(21) Appl. No.: 18/806,105

(22) Filed: Aug. 15, 2024

(51) Int. Cl. H01L 21/48; H01L 21/56; H01L 23/00; H01L 25/00

(52) U.S. Cl. CPC H01L 21/4857; H01L 21/561; H01L 24/97; H01L 25/50; H01L 24/81; H01L 2224/81986; H01L 2224/97

(57) ABSTRACT

A method is provided, including forming a wafer structure including a sacrificial layer between first and second substrates; forming first sacrificial structures within the second substrate in the spacing regions; forming second sacrificial structure within the second substrate; forming conductive vias through the second substrate in the die regions; forming dielectric layers over the second substrate and forming conductive features in the dielectric layers in the die regions; forming first windows through the dielectric layers and extending to the first sacrificial structures; forming second window through the dielectric layers and extending to the second sacrificial structure; forming a protective layer over the dielectric layers and filling the first windows; attaching a carrier substrate to the protective layer; removing the sacrificial layer, first sacrificial structures, and second sacrificial structure by flowing an etchant through the at least one second window; removing the protective layer; and detaching the carrier substrate.

### BACKGROUND

The semiconductor industry has continuously grown due to continuous improvements in integration density of a variety of electronic components (e.g., transistors, diodes, resistors, capacitors, etc.). For the most part, these improvements in integration density have come from successive reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. For example, chip-on-wafer-on-substrate (CoWoS) packaging is a well-known 3D integrated circuit (3DIC) package architecture in the semiconductor industry, in which at least two dies may be connected to an interposer, which is in turn connected to a package substrate.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 3, 4A to 4B, 5A to 5B, 6 to 9, 10A to 10C, 11, 12A to 12B, and 13 to 17 illustrate various views of intermediate steps of forming a package component (e.g., a chip-on-wafer (CoW) device), in accordance with some embodiments.

FIG. 18 illustrates a cross-sectional view of a CoW device, in accordance with some embodiments.

FIG. 19 illustrates a plan view (e.g., top view) of an interposer wafer showing the arrangement of interposer die regions, die-to-die spacing windows, and sacrificial layer removal windows on the interposer wafer, in accordance with some embodiments.

FIG. 20 illustrates a cross-sectional view of a chip-on-wafer-on-substrate (CoWoS) package that includes a CoW device attached to a package substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

In chip-on-wafer-on-substrate (CoWoS) packaging, silicon interposers are usually used to provide much finer die-to-die interconnections, thereby increasing performance and reducing power consumption. In these situations, power and signal lines may be passed through the interposer by way of through substrate vias (TSVs) in the interposer. During the manufacturing process, a backside grinding process is required to expose TSVs, so the thickness of the substrate of the interposer cannot be too thin, which results in longer TSVs. This causes the electrical connection resistance of the TSVs to increase. Moreover, the backside grinding process can easily cause the interposer surface to be depressed, resulting in worse bump landing on the interposer. In the final step, a die saw process also is required to separate individual interposers in the interposer wafer, which typically uses a mechanical saw to cut the interposer wafer along the scribe lines. Such a process can easily damage the interposers, and setting scribe lines also causes area loss on the interposer wafer.

Embodiments of the present disclosure provide a novel interposer formation method that introduces buried sacrificial layers or structures for separating individual interposers from the interposer wafer and exposing TSV structures during sacrificial layer removal. Accordingly, the interposer die saw process and backside grinding process can be omitted (i.e., replaced by a sacrificial layer removal process). As a result, thinner interposer substrates and shorter TSV structures can be achieved with less damage to the interposers. Moreover, there are no scribe lines for the die saw process, so the wafer area utilization can be maximized. Other advantages will be described below. The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

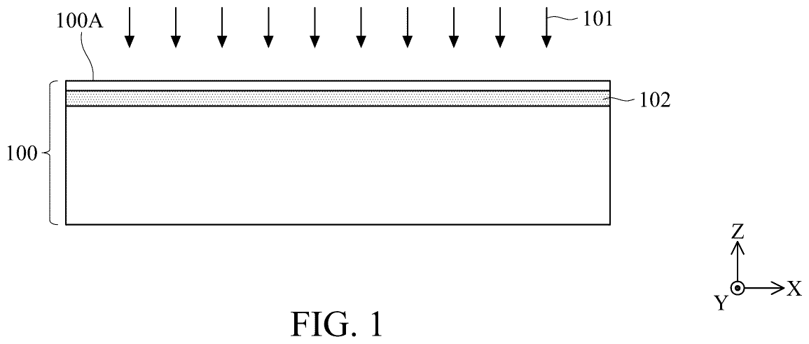

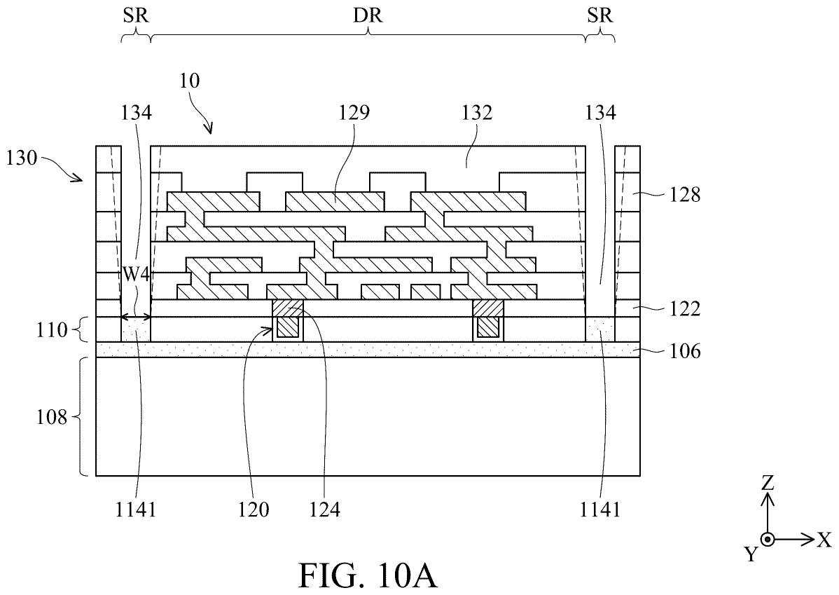

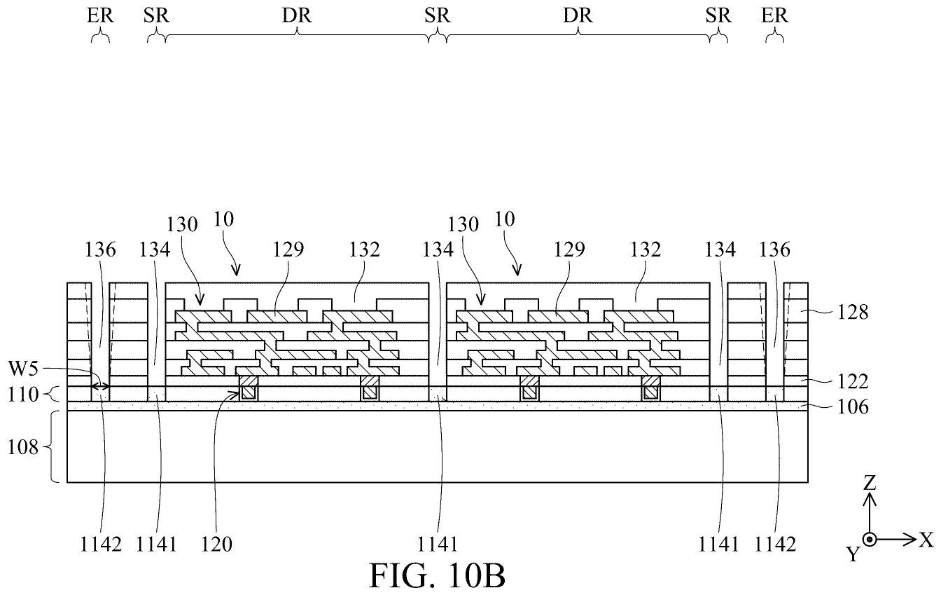

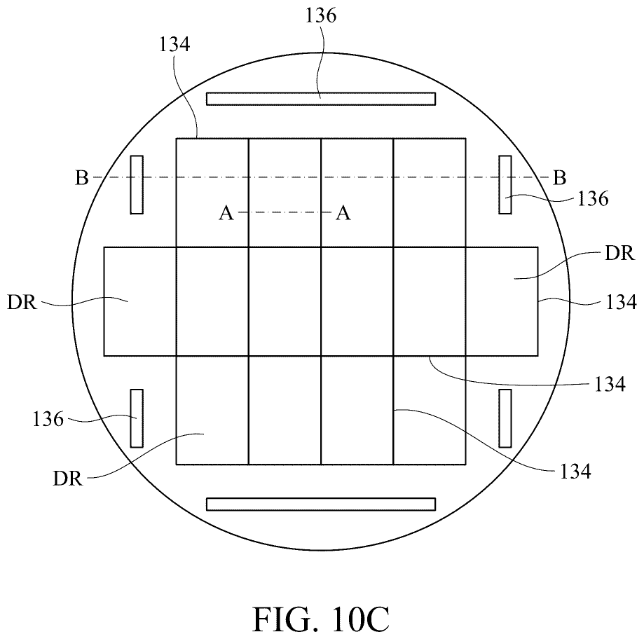

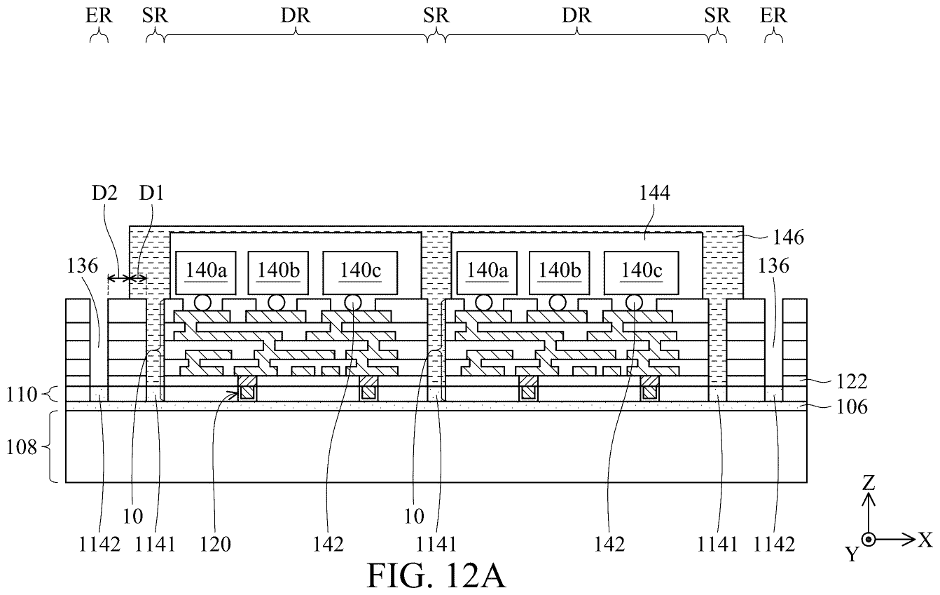

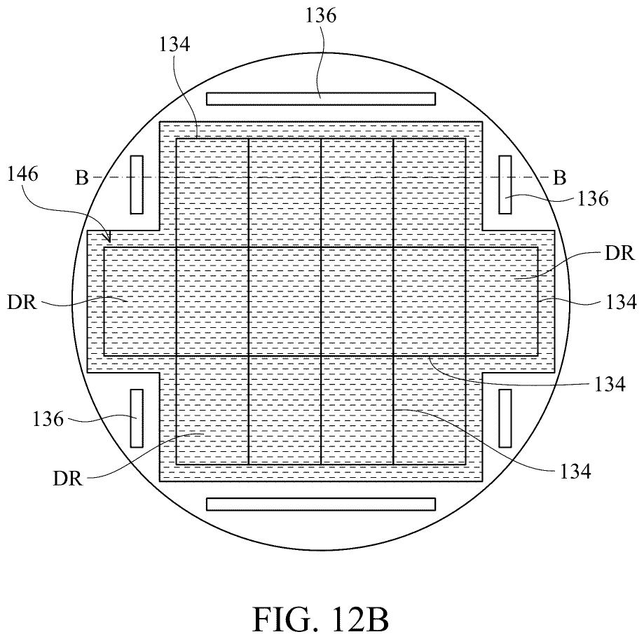

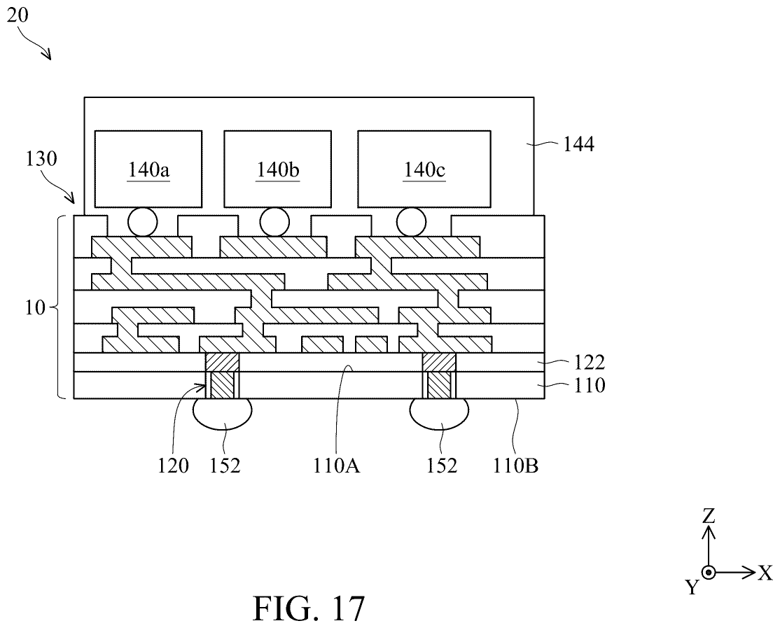

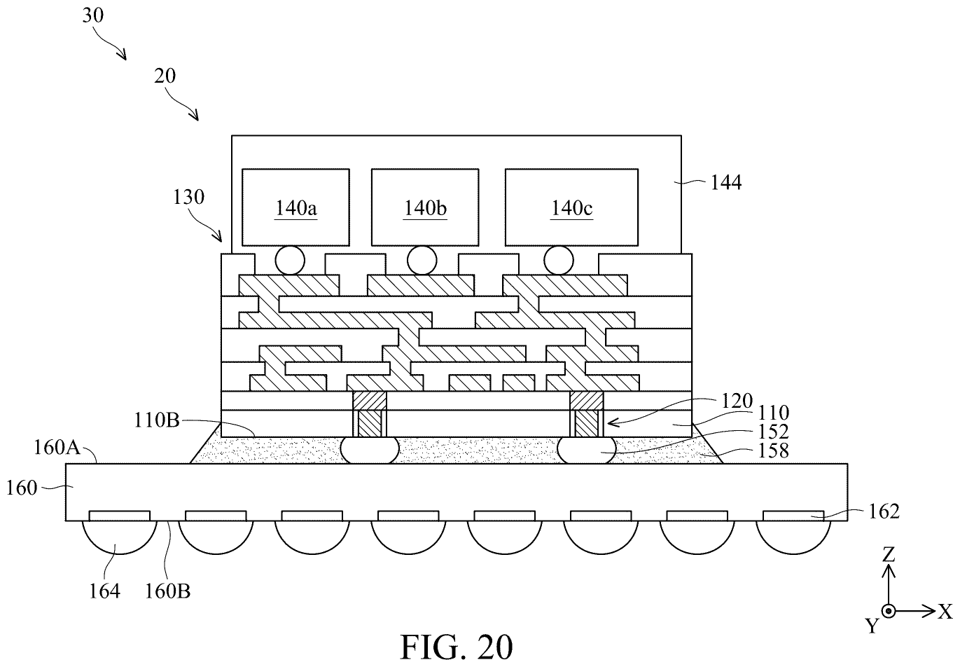

FIGS. 1 to 3, 4A to 4B, 5A to 5B, 6 to 9, 10A to 10B, 11, 12A, and 13 to 17 illustrate cross-sectional views of intermediate steps of forming a package component (see, for example, FIG. 17), and FIGS. 10C and 12B illustrate plan views (e.g., top) of intermediate steps of forming the package component, in accordance with some embodiments. The package component is a chip-on-wafer (CoW) device and may subsequently be attached to a package substrate to form a chip-on-wafer-on-substrate (CoWoS) package (see, for example, FIG. 20).

FIG. 1 illustrates that an implantation process 101 is preformed on a silicon substrate 100, in accordance with some embodiments. The silicon substrate 100 can be a silicon wafer. During the implantation process 101, a dielectric material is implanted below the top surface 100A of the silicon substrate 100 to form a buried dielectric 102. In some embodiments, the implantation process 101 is an oxygen implantation process, such as a separation by implanted oxygen (SIMOX) process, and the buried dielectric 102 is an oxygen-rich layer. The oxygen implantation process may include ion implantation of oxygen (e.g., at a dose in the range of 5×10¹⁴ atoms/cm² to 5×10¹⁸ atoms/cm²) with substrate temperature greater than about 600 degrees Celsius, in some cases. In alternative embodiments, the implantation process 101 is a nitrogen implantation process, such as a separation by implanted nitrogen (SIMNI) process, and the buried dielectric 102 is a nitrogen-rich layer. Other dielectric materials and other buried dielectrics are also possible.

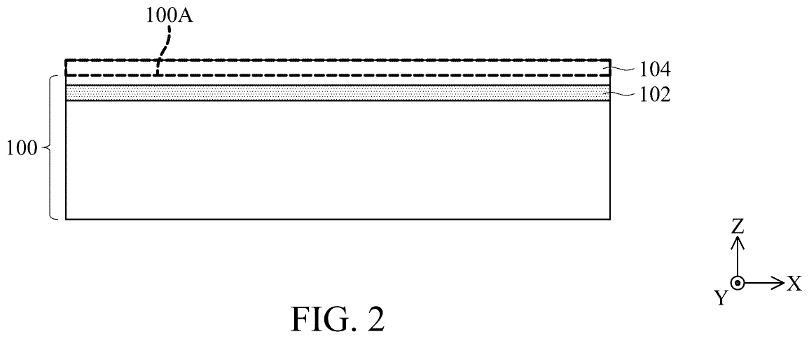

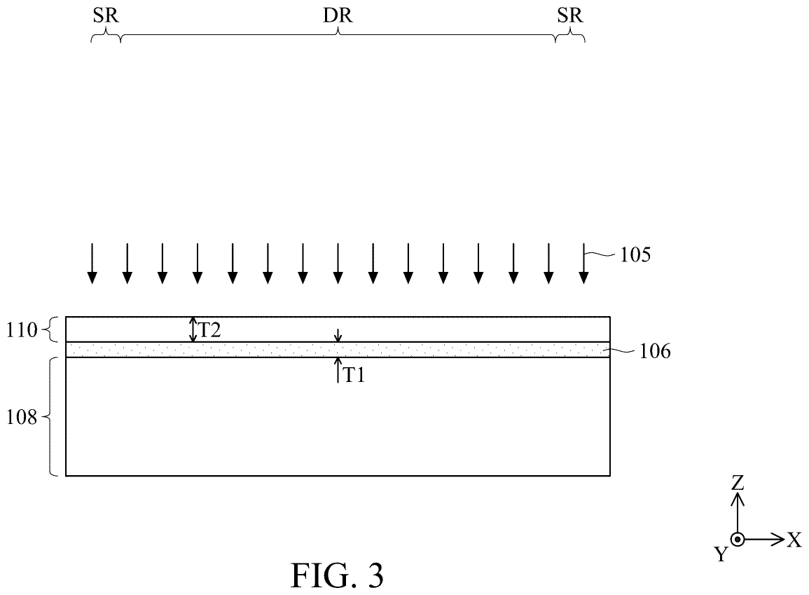

FIG. 2 illustrates that an optional epitaxy layer 104 (depicted in dashed lines) is formed on the (entire) top surface 100A of the silicon substrate 100 using an epitaxy process, in accordance with some embodiments. The epitaxy process may include chemical vapor deposition (CVD) techniques (e.g., vapor-phase epitaxy (VPE) and/or ultra-high vacuum CVD (UHV-CVD)), molecular beam epitaxy, or other suitable epitaxy processes. In some embodiments, the epitaxy layer 104 may be the same material as the silicon substrate 100 (e.g., silicon) to increase the thickness of the structure (e.g. a second substrate 110 shown in FIG. 3) above the buried dielectric 102. However, other materials for epitaxy layer 104 may be used, such as silicon carbide or any other suitable semiconductor materials. In other embodiments, the epitaxy layer 104 may not be formed if the thickness of the second (or interposer) substrate 110 (see FIG. 3) already meets the requirements.

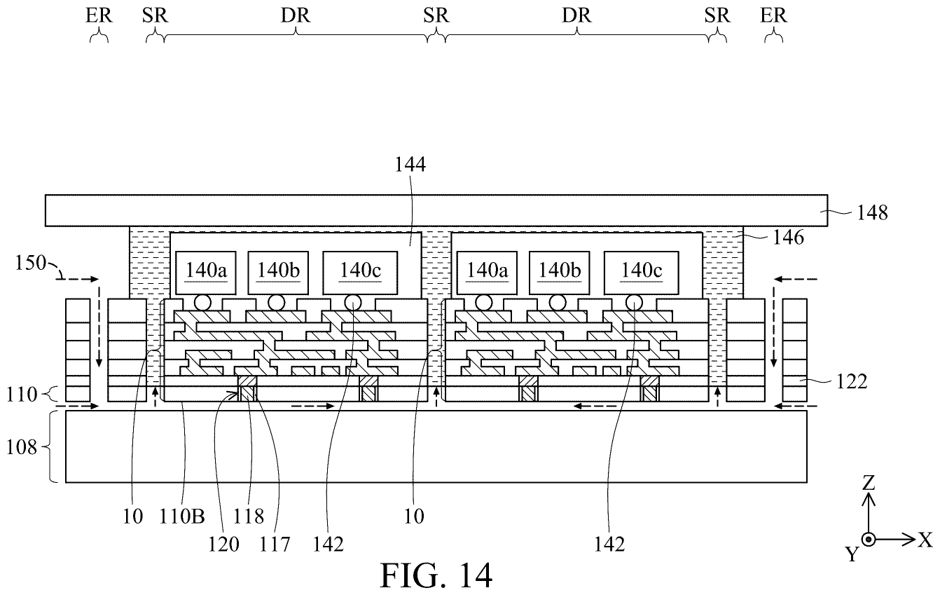

FIG. 3 illustrates that the silicon substrate 100 is annealed (marked as 105) at a high temperature (e.g., about 1300 degrees Celsius) to convert the buried dielectric 102 (e.g., oxygen-rich layer) into an oxide layer 106 (e.g., silicon oxide), in accordance with some embodiments. In the case where the buried dielectric 102 is a nitrogen-rich layer, the annealing process 105 converts it to a nitride layer 106 (e.g., silicon nitride). It should be noted that the oxide/nitride layer 106 will be removed in a subsequent sacrificial layer removal process (see, for example, FIG. 14), and is therefore also referred to herein as a (dielectric) sacrificial layer 106. Other dielectric materials suitable for the sacrificial layer 106 embedded in the silicon substrate 100 may also be used.

In some embodiments, the sacrificial layer 106 extends horizontally (e.g., in the X-Y plane) across the entire silicon substrate 100, and may or may not reach the edges of the silicon substrate 100 (silicon wafer). In some embodiments, the thickness T1 (e.g., in the Z-direction) of the sacrificial layer 106 may be greater than 0.2 microns (μm) to facilitate the flow of etchant used in the sacrificial layer removal process (see FIG. 14), but embodiments of the present disclosure are not limited thereto.

In the discussion herein, the structure below the sacrificial layer 106 may be referred to as a first (semiconductor) substrate 108 and the structure above the sacrificial layer 106 may be referred to as a second (semiconductor) substrate 110. The first substrate 108 will be removed after the sacrificial layer removal process (see FIG. 14), and the second substrate 110 remains after the sacrificial layer removal process and is used as an interposer substrate (hence also referred to as the interposer substrate 110 below). The resulting structure shown in FIG. 3 can be collectively referred to as an interposer wafer.

In some embodiments, the thickness T2 (e.g., in the Z-direction) of the interposer substrate 110 may be in a range between about 2 μm and about 500 μm (in such cases, the ratio of T1/T2 may be less than about 0.1), although smaller or larger thicknesses are possible. Compared with existing interposer formation methods, since no backside grinding process is adopted to expose TSVs, the thickness T2 of interposer substrate 110 formed by the method embodiments of the present disclosure can be relatively thin (for example, less than 50 μm, or even smaller), which will be described in more detail later.

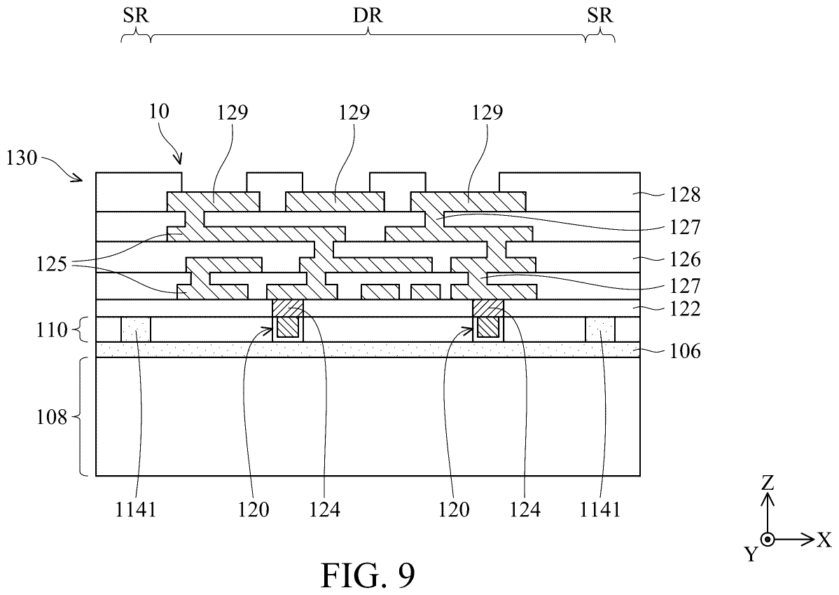

FIG. 3 also illustrates that the interposer substrate 110 has a plurality of die regions DR (for simplicity, only one die region DR is shown) and die-to-die spacing regions SR. Although not shown, in a plan (or top) view each die region DR is bounded by a plurality of die-to-die spacing regions SR. In subsequent steps, an interconnect structure 130 may be formed over the interposer substrate 110 in each die region DR (see, for example, FIG. 9). The die-to-die spacing regions SR are configured to form embedded (or buried) sacrificial layers (or structures) that will be removed during the sacrificial layer removal process (see FIG. 14). It should be noted that the dimension (e.g., width) of the die-to-die spacing regions SR is smaller than the scribed lines used for the die saw process (e.g., less than about 1 μm), which helps improve wafer area utilization (i.e., reduce area loss).

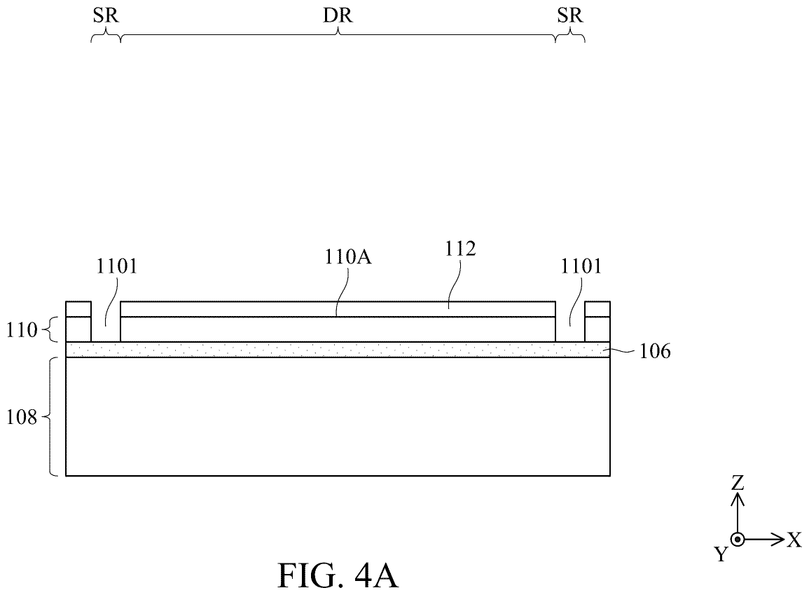

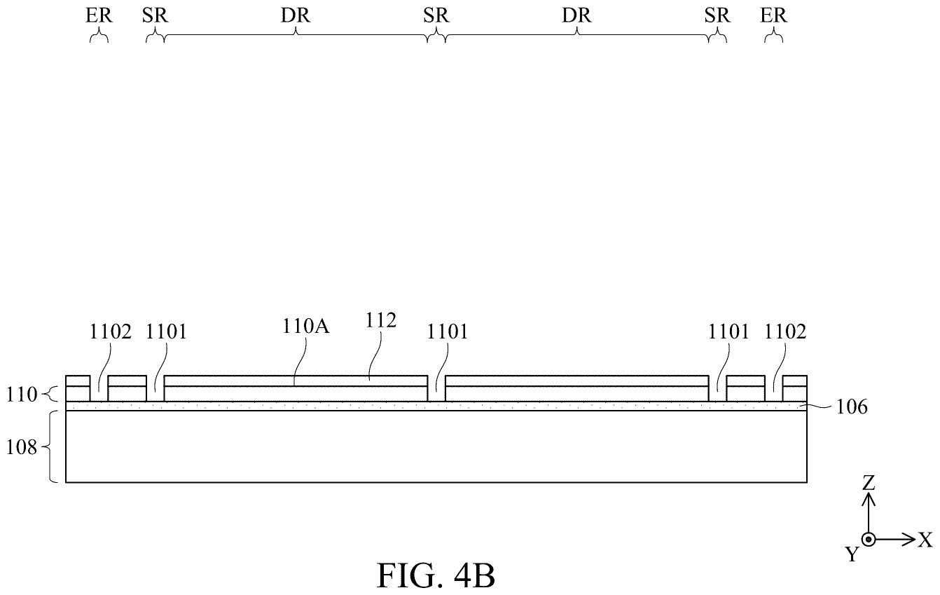

FIGS. 4A and 4B illustrate that a patterned mask 112 is formed over the upper surface 110A of the interposer substrate 110, in accordance with some embodiments. Compared with FIG. 4A, FIG. 4B shows more die regions DR of the interposer substrate 110 and further shows a plurality of sacrificial layer removal (or etching) regions ER disposed adjacent to edges (not specifically marked) of the interposer substrate 110. The patterned mask 112 may be lithographically patterned to form first openings and second openings (not specifically marked) through the mask 112. The (top-view) pattern of first openings may correspond to the (top-view) pattern of die-to-die spacing regions SR, and the (top-view) pattern of second openings may correspond to the (top-view) pattern of sacrificial layer removal regions ER.

Still referring to FIGS. 4A and 4B, an anisotropic etch process (e.g., dry etch process) may then be performed through the patterned mask 112 to remove portions of the interposer substrate 110 to form first openings 1101 and second openings 1102 through the interposer substrate 110. The first openings 1101 and second openings 1102 may fully extend through the interposer substrate 110 to expose underlying sacrificial layer 106. In some embodiments, the first openings 1101 and second openings 1102 may each have substantially vertical sidewalls for maximum area efficiency (i.e., reduce area loss in the die regions DR). The patterned mask 112 may then be removed using a suitable process, such as ashing or dissolution by a solvent.

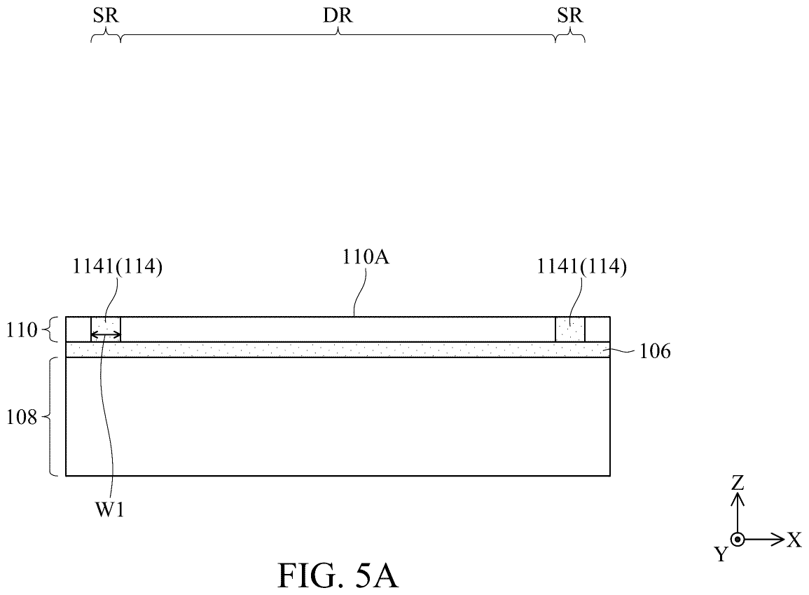

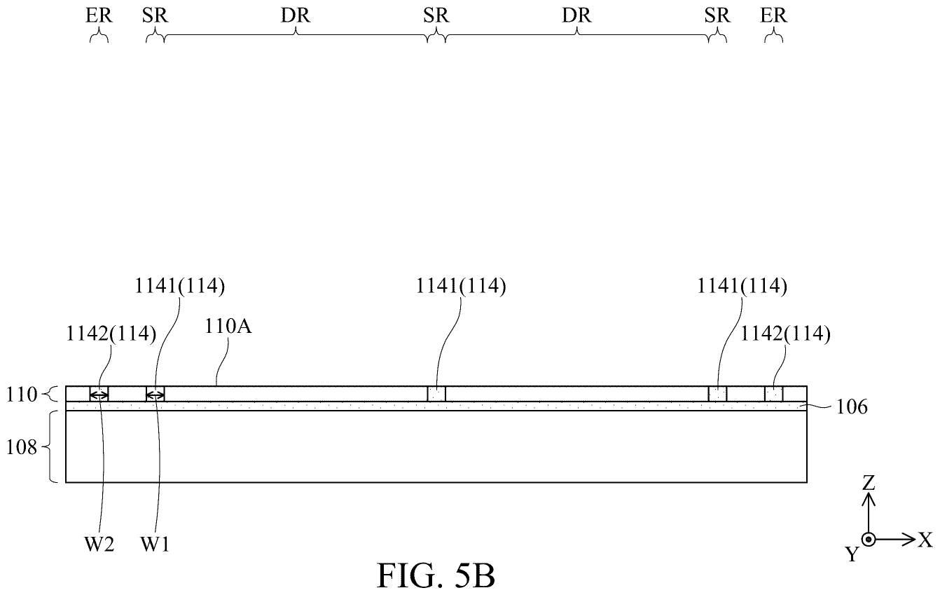

FIGS. 5A and 5B illustrate the formation of first (dielectric) sacrificial structures 1141 and second (dielectric) sacrificial structures 1142 in the interposer substrate 110, in accordance with some embodiments. The formation of first sacrificial structures 1141 and second sacrificial structures 1142 may include depositing a dielectric material 114 over the upper surface 110A of the interposer substrate 110 and filling the first openings 1101 and second openings 1102 (see FIGS. 4A and 4B) of the interposer substrate 110. In some embodiments, the dielectric material 114 may be the same material as the sacrificial layer 106 (e.g. silicon oxide or silicon nitride), and may be formed by a deposition process such as CVD, spin coating, lamination, or the like.

A planarization process (e.g., a chemical mechanical planarization (CMP) process or a grinding process) may then be performed to remove excess dielectric material 114 along the upper surface 110A of the interposer substrate 110. The remaining portions of the dielectric material 114 located within the first openings 1101 and second openings 1102 form the first sacrificial structures 1141 and the second sacrificial structures 1142 embedded in the interposer substrate 110. In this way, the (top-view) pattern of first sacrificial structures 1141 may correspond to the pattern of die-to-die spacing regions SR, and the (top-view) pattern of second sacrificial structures 1142 may correspond to the pattern of sacrificial layer removal regions ER.

As shown in FIGS. 5A and 5B, the first sacrificial structures 1141 and the second sacrificial structures 1142 are connected to the sacrificial layer 106 so that they can be removed together during the sacrificial layer removal process (see FIG. 14). In some embodiments, the width W1 (e.g., in the X-direction) of each first sacrificial structure 1141 may be greater than 0.2 μm and the width W2 (e.g., in the X-direction) of each second sacrificial structure 1142 may be greater than 0.2 μm to facilitate the flow of etchant used in the sacrificial layer removal process (see FIG. 14), but embodiments of the present disclosure are not limited thereto.

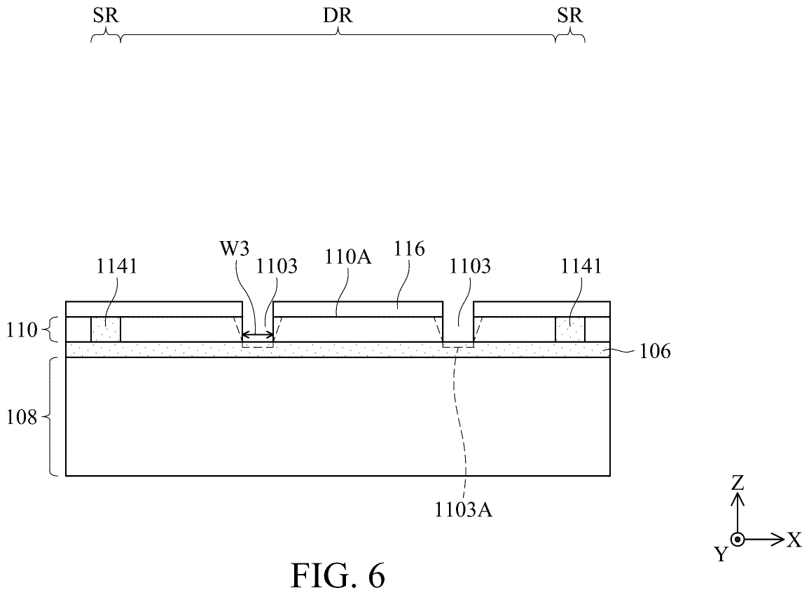

FIG. 6 illustrates that a patterned mask 116 is formed over the upper surface 110A of the interposer substrate 110 after the embedded sacrificial structures 1141-1142 are formed, in accordance with some embodiments. The patterned mask 116 may be lithographically patterned to form openings (not specifically marked) through the mask 116. The (top-view) pattern of the openings may correspond to the (top-view) pattern of via openings 1103 that may be subsequently formed through the interposer substrate 110. The via openings 1103 are formed in each die region DR.

Still referring to FIG. 6, an anisotropic etch process (e.g., dry etch process) may then be performed through the patterned mask 116 to remove portions of the interposer substrate 110 to form via openings 1103 through the interposer substrate 110. The via openings 1103 may fully extend through the interposer substrate 110 to expose underlying sacrificial layer 106. In various embodiments, each via opening 1103 may have substantially vertical sidewalls (e.g., the opening width W3 of the via opening 113 is consistent from top to bottom), or may have sloping sidewalls (depicted in dashed lines) (e.g., the opening width W3 of the via opening 113 gradually decrease from top to bottom). In some embodiments, the etch process may also remove portions of the sacrificial layer 106 such that the bottom 1103A of via opening 1103 extends slightly into the sacrificial layer 106 (depicted in dashed lines). The patterned mask 116 may then be removed via a suitable process, such as by ashing or dissolution by a solvent.

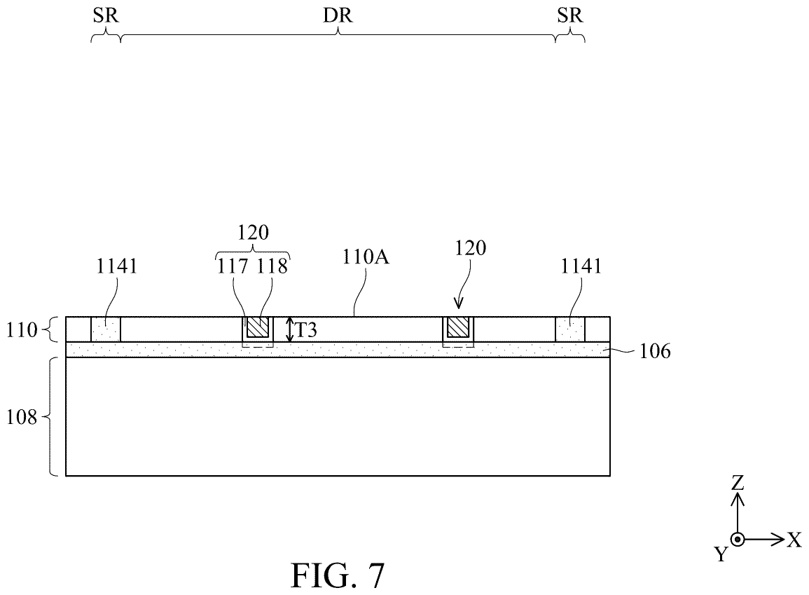

FIG. 7 illustrates the formation of conductive or metal pillars 120 in the interposer substrate 110 after the patterned mask 116 is removed, in accordance with some embodiments. The formation of metal pillars 120 may include first forming a liner 117, such as a diffusion barrier layer (e.g., a layer made of tantalum, tantalum nitride, titanium, titanium nitride, etc.), over the upper surface 110A of the interposer substrate 110 and in the via openings 113 (e.g., along the sidewalls and bottom of each via opening 113). The liner 117 may be formed using a suitable deposition process such as atomic layer deposition (ALD) or the like. In some embodiments, a seed layer (not shown), which may include copper or a copper alloy, may then be deposited over the liner 117. A conductive material 118 may then be formed over the seed layer (and filling the via openings 113) using, for example, electroplating or electro-less plating. The conductive material 118 may include, for example, a metal or a metal alloy such as copper, silver, gold, tungsten, cobalt, aluminum, or alloys thereof.

A planarization process (e.g., a CMP process or a grinding process) may then be performed to remove excess conductive material 118 and liner 117 along the upper surface 110A of the interposer substrate 110. The remaining portions of the conductive material 118 and liner 117 located within the via openings 113 form the metal pillars 120 (sometimes called through substrate vias (TSVs) 120) embedded in the interposer substrate 110. Therefore, the thickness or length T3 (e.g., in the Z-direction) of TSVs 120 is substantially equal to the thickness T2 (see FIG. 3) of the interposer substrate 110. Due to a relatively small thickness of the interposer substrate 110 (as mentioned above), shorter TSVs 120 can also be achieved, thereby increasing electrical connection conductivity (e.g., less connection resistance).

In cases where the bottom 1103A of the via opening 1103 extends slightly into the sacrificial layer 106 (see FIG. 6), the liner 117 of TSVs 120 may also extend slightly into the sacrificial layer 106 (depicted in dashed lines). This facilitates making the exposed conductive material 118 of TSVs 120 coplanar with the lower surface 110B of the interposer substrate 110 after removing the liner 117 during the sacrificial layer removal process (see FIG. 14).

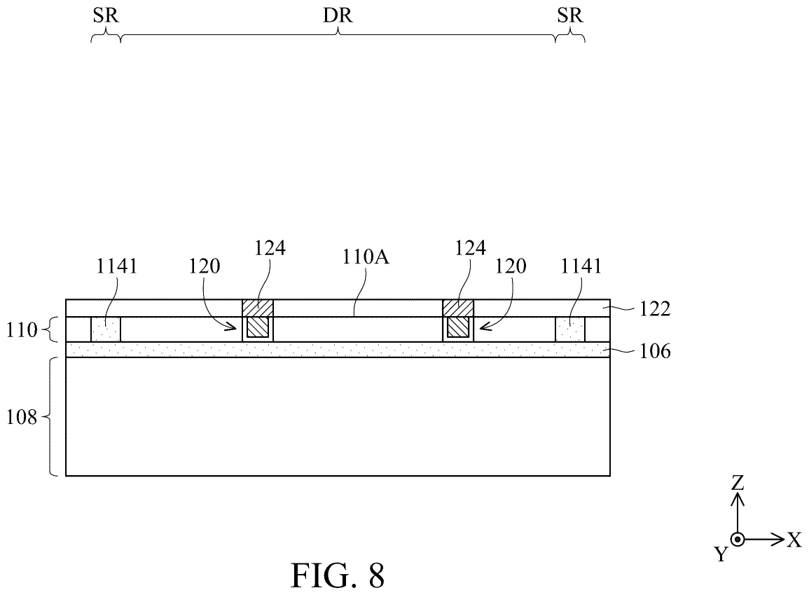

FIG. 8 illustrates that an inter-layer dielectric (ILD) layer 122 is formed over the upper surface 110A of the interposer substrate 110 after the TSVs 120 are formed, in accordance with some embodiments. The ILD layer 122 may be formed of or comprise silicon oxide, Phospho Silicate Glass (PSG), Boro Silicate Glass (BSG), Boron-Doped Phospho Silicate Glass (BPSG), Fluorine-Doped Silicate Glass (FSG), or the like, and may be formed using a suitable deposition process such as spin coating, CVD, flowable CVD (FCVD), plasma enhanced CVD (PECVD), or the like.

FIG. 8 also illustrates that contact plugs 124 are formed in the ILD layer 122 and in contact with the underlying TSVs 120. The contact plugs 124 are used to electrically connect the TSVs 120 and an overlying interconnect structure 130 (see FIG. 10) that will be subsequently formed. The contact plugs 124 may be formed using materials and techniques similar to those described previously for forming the TSVs 120, so the details are not repeated here.

FIG. 9 illustrates that in each die region DR an interconnect structure 130 is formed over the ILD layer 122 and contact plugs 124, in accordance with some embodiments. The interconnect structure 130 may include metal lines 125 and vias 127 (which may collectively be referred to as conductive features), which are formed in inter-metal dielectric (IMD) layers 126. In some embodiments, some of the IMD layers 126 are formed of low-k dielectric materials having dielectric constant values (k-values) lower than about 3.5 or 3.0. The IMD layers 126 may be formed of or comprise a carbon-containing low-k dielectric material, Hydrogen Silses Quioxane (HSQ), MethylSilsesQuioxane (MSQ), or the like. In other embodiments, some or all of the IMD layers 126 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, silicon oxynitride, silicon oxycarbide, aluminum oxide, aluminum nitride, or the like, or multi-layers thereof, are formed between the IMD layers 126, and are not shown for simplicity.

The metal lines 125 and vias 127 are formed (e.g., embedded) in the IMD layers 126. The metal lines 125 at the same level are collectively referred to as a metal layer hereinafter. In some embodiments, the interconnect structure 130 includes a plurality of metal layers that are interconnected through the vias 127. The metal lines 125 and vias 127 may be formed of or comprise copper or copper alloys, or other metals. The formation process for the metal lines 125 and vias 127 may include single damascene processes or dual damascene processes.

Still referring to FIG. 9, the interconnect structure 130 also includes one or more passivation layers 128 formed over the IMD layers 126, in accordance with some embodiments. The passivation layers 128 may be undoped silicate-glass (USG) layers, polymer layers (which may be formed of polyimide, polybenzoxazole (PBO), or the like), or the like. The passivation layers 128 are denser than the IMD layers 126 (e.g., low-k dielectric layers), and have the function of isolating the low-k dielectric layers from detrimental chemicals and gases such as moisture in external environment.

In accordance with some embodiments, there may be (top) metal pads 129 formed over the interconnect structure 130 and electrically connected to the metal lines 125 and vias 127. The metal pads 129 are formed in the passivation layer 128 and are exposed through openings (not specifically marked) of the passivation layer 128. The metal pads 129 may be formed of or comprise copper, nickel, titanium, palladium, or the like, or alloys thereof.

After forming the above structures, a plurality of identical interposers 10 can be obtained in the interposer wafer, as shown in FIG. 9 (for simplicity, only one interposer 10 in one die region DR is shown).

FIGS. 10A and 10B illustrate that a patterned mask 132 is formed over the passivation layers 128 of the interconnect structures 130 and covers the exposed metal pads 129, in accordance with some embodiments. The patterned mask 132 may be lithographically patterned to form first openings and second openings (not specifically marked) through the mask 132. The (top-view) pattern of first openings may correspond to the (top-view) pattern of die-to-die spacing regions SR, and the (top-view) pattern of second openings may correspond to the (top-view) pattern of sacrificial layer removal regions ER.

Still referring to FIGS. 10A and 10B, an anisotropic etch process (e.g., dry etch process) may then be performed through the patterned mask 132 to remove portions of the interconnect structures 130 and ILD layer 122 to form die-to-die spacing windows 134 and sacrificial layer removal windows 136 through the interconnect structures 130 and ILD layer 122. The die-to-die spacing windows 134 may fully extend through the interconnect structures 130 and ILD layer 122 to expose underlying first sacrificial structures 1141, and the sacrificial layer removal windows 136 may fully extend through the interconnect structures 130 and ILD layer 122 to expose underlying second sacrificial structures 1142. The patterned mask 136 may then be removed using a suitable process, such as ashing or dissolution by a solvent.

In various embodiments, each die-to-die spacing window 134 may have substantially vertical sidewalls (e.g., the window width W4 of the die-to-die spacing window 134 is consistent from top to bottom), or may have sloping sidewalls (depicted in dashed lines) (e.g., the window width W4 of the die-to-die spacing window 134 gradually decrease from top to bottom), as shown in FIG. 10A. The bottom window width W4 of the die-to-die spacing window 134 may be equal to or greater than the width W1 (see FIG. 5A) of the underlying first sacrificial structure 1141. Similarly, each sacrificial layer removal window 136 may have substantially vertical sidewalls (e.g., the window width W5 of the sacrificial layer removal window 136 is consistent from top to bottom), or may have sloping sidewalls (depicted in dashed lines) (e.g., the window width W5 of the sacrificial layer removal window 136 gradually decrease from top to bottom). The bottom window width W5 may be equal to or greater than the width W2 (see FIG. 5B) of the underlying second sacrificial structure 1142. In some embodiment, the top window width W5 may be at least equal to or greater than 0.5 μm to facilitate the flow of etchant used in the sacrificial layer removal process (see FIG. 14), but embodiments of the present disclosure are not limited thereto.

FIG. 10C illustrates a plan view (e.g., top view) of the interposer wafer showing the arrangement of (interposer) die regions DR, die-to-die spacing windows 134, and sacrificial layer removal windows 136 on the interposer wafer, in accordance with some embodiments, wherein FIGS. 10A and 10B are taken along lines A-A and B-B in FIG. 10C. As shown in FIG. 10C, the die regions DR may be arranged in a matrix with a plurality of die-to-die spacing windows 134 around each die region DR. A plurality of separate sacrificial layer removal windows 136 may be disposed adjacent to edges of the interposer wafer. It should be understood that the configurations or arrangements shown in FIG. 10C are illustrative examples only, and are not intended to be, and should not be construed to be, limiting to the present disclosure. Many alternatives and modifications will be apparent to those skilled in the art, once informed by the present disclosure.

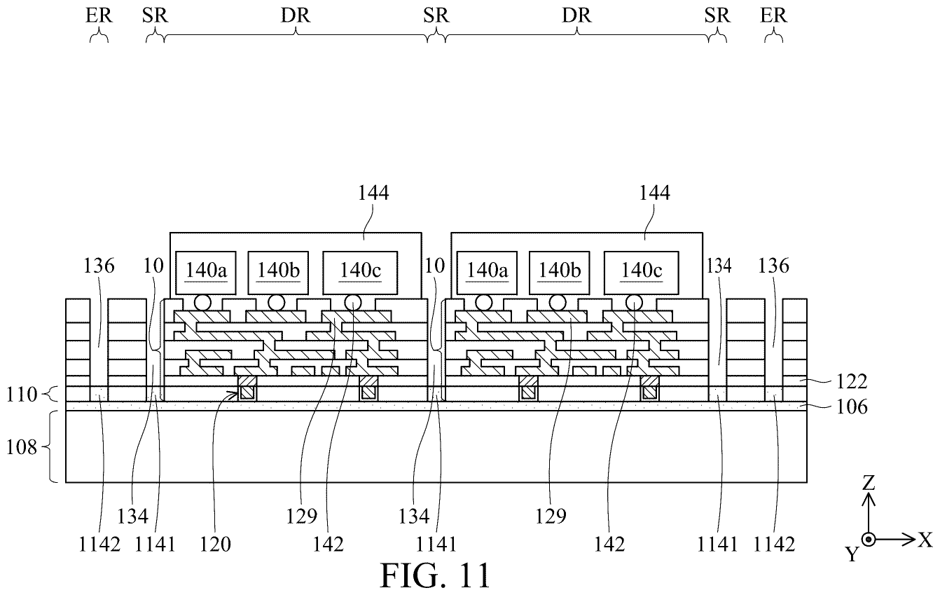

FIG. 11 illustrates that a plurality of integrated circuit (IC) dies 140a, 140b, and 140c are attached (e.g., bonded) to the exposed metal pads 129 of each interposer 10 (in each die region DR) using electrical connectors 142, in accordance with some embodiments. The IC dies 140a-140c may each be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, wide input/output (WIO) memory, NAND flash, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), an integrated passive device (IPD), the like, or combinations thereof. In some embodiments, the IC dies 140a-140c may include at least two types of IC dies.

The electrical connectors 142 may be metal bumps (e.g., microbumps), and may electrically connect conductive bonding pads (not shown) on the bottom surfaces of the IC dies 140a-140c to the exposed metal pads 129 of the corresponding interposer 10. In one non-limiting embodiment, the electrical connectors 142 in the form of microbumps may include a plurality of first metal stacks (such as Cu—Ni—Cu stacks) located on the bottom surfaces of the IC dies 140a-140c, and a plurality of second metal stacks (such as Cu—Ni—Cu stacks) located on the top surface of the corresponding interposer 10. A solder material, such as tin (Sn), may be located between respective first and second metal stacks to electrically connect the IC dies 140a-140c to the corresponding interposer 10. Other suitable materials for the electrical connectors 142 are within the contemplated scope of disclosure.

In some embodiments, an underfill material (not shown) may be dispensed into the gaps between the IC dies 140a-140c and the corresponding interposer 10 to surround and protect the electrical connectors 142. The underfill material may be any acceptable material, such as a polymer, epoxy, molding underfill, or the like, and may be formed by a capillary flow process or another suitable deposition method.

FIG. 11 also illustrates that an encapsulant 144 is formed over various components on each interposer 10, in accordance with some embodiments. The encapsulant 144 may be a molding compound, epoxy, or the like, and may be applied by compression molding, transfer molding, or the like. A curing step is performed to cure the encapsulant 144, such as a thermal curing, an Ultra-Violet (UV) curing, or the like. In some embodiments, the IC dies 140a-140c may be buried in the encapsulant 144, as shown in FIG. 11. In other embodiments, after the curing of the encapsulant 144, a planarization process (e.g., a CMP process or a grinding process) may be performed to remove excess portions of the encapsulant 144 along the upper surfaces of the IC dies 140a-140c. Accordingly, upper surfaces of the IC dies 140a-140c are exposed and are level with the top surface of the encapsulant 144.

FIGS. 12A and 12B illustrate the formation of a protective layer 146 over the resulting structure in FIG. 11, in accordance with some embodiments, wherein FIG. 12A is taken along line B-B in FIG. 12B. As shown in FIGS. 12A and 12B, the protective layer 146 may be formed to cover various components on the interposers 10 in all die regions DR and fully fill all die-to-die spacing windows 134 (see FIG. 11), to protect the interposers 10 (e.g., the interconnect structures 130) and various overlying components from being damaged by etchant used in a sacrificial layer removal process (see FIG. 14).

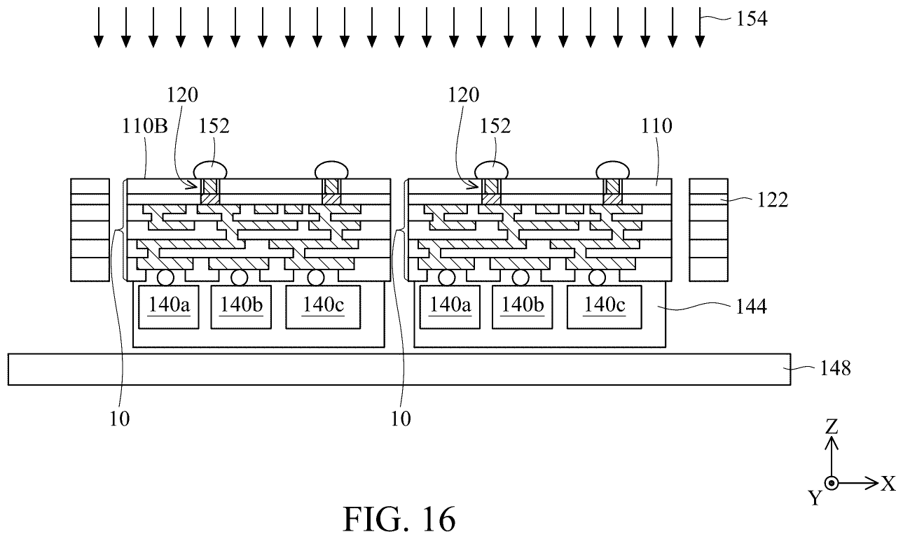

To adequately serve its protective function, the protective layer 146 may have a material composition such that it has sufficient etching selectivity with the materials of the sacrificial layer 106, first sacrificial structures 1141 and second sacrificial structures 1142. In the illustrated embodiments, this means that the protective layer 146 has etching selectivity with silicon oxide or silicon nitride. For example, the silicon oxide or silicon nitride will be etched away at a significantly higher rate than the protective layer 146 during the sacrificial layer removal process. Moreover, the protective layer 146 may comprise a material that can be easily removed in a subsequent removal step (see, for example, FIG. 16).

In some embodiments, the protective layer 146 is a release layer, such as an epoxy-based thermal-release material, which loses its adhesive property when heated, such as a light-to-heat-conversion (LTHC) release coating; an ultra-violet (UV) glue, which loses its adhesive property when exposed to UV lights; or the like. In some embodiments, the protective layer 146 is an adhesive, such as a suitable epoxy, die attach film (DAF), or the like. In some embodiments, the protective layer 146 is a polymer layer such as a layer of polyimide, PBO, benzocyclobutene (BCB), or another suitable polymer-based dielectric material. The protective layer 146 may be formed using a suitable deposition process such as spin coating, CVD, lamination, or the like.

In some embodiments, a portion of the protective layer 146 extends laterally beyond the outermost die-to-die spacing window 134, wherein the lateral extent D1 (e.g., in the X-direction) of the portion may be greater than 10 μm to ensure that the protective layer 146 can fully fill all die-to-die spacing windows 134. In some embodiments, the lateral distance D2 (e.g., in the X-direction) between a sidewall of the protective layer 146 and the innermost edge of the adjacent sacrificial layer removal window 136 may be greater than 5 μm to ensure that the protective layer 146 does not extend into the sacrificial layer removal windows 136. However, other values for the lateral extent D1 and lateral distance D2 may be used. In some embodiments, the ratio of D2/D1 may be about 0.5.

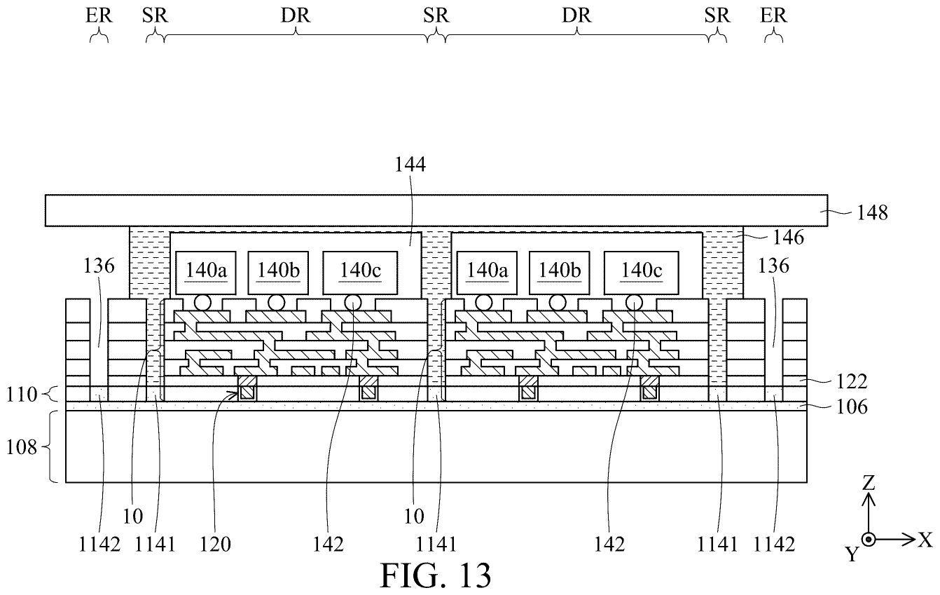

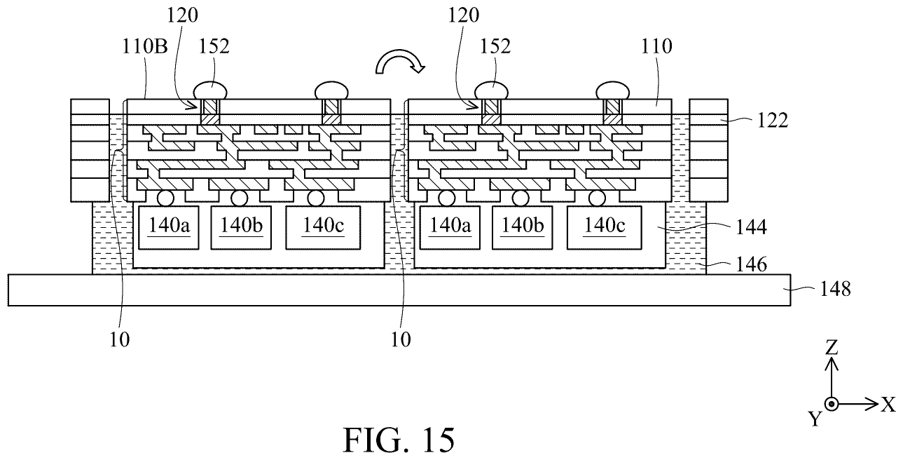

FIG. 13 illustrates that the attachment of a carrier substrate 148 to the protective layer 146, in accordance with some embodiments. The carrier substrate 148 is provided to temporarily secure multiple interposers 10 (and various components thereon) after they are separated from the interposer wafer (see, for example, FIG. 15). In some embodiments, the carrier substrate 148 may include an optically transparent substrate such as a glass substrate or a sapphire substrate, or may comprise a semiconductor substrate such as a silicon substrate. In some embodiments, the carrier substrate 148 may be directly attached (e.g., bonded) to the protective layer 146 through the adhesive property of the protective layer 146. In other embodiments, the carrier substrate 148 may be attached to the protective layer 146 using an additional adhesive layer (not shown), such as an UV tape, a pressure sensitive tape, a radiation curable tape, combinations of these, or the like.

FIG. 14 illustrates that the resulting structure in FIG. 13 is subjected to a sacrificial layer removal process to remove the sacrificial layer 106, the first sacrificial structures 1141 and the second sacrificial structures 1142, in accordance with some embodiments. In some embodiments, the sacrificial layer removal process is performed using a (selective) wet etch process, which includes using etchant 150 to flow into the interposer wafer through the sacrificial layer removal windows 136 to remove (e.g., etch away) the sacrificial layer 106, the first sacrificial structures 1141 and the second sacrificial structures 1142 (the flow path of etchant 150 is shown as dashed lines with arrow). As mentioned above, since the sacrificial layer 106, the first sacrificial structures 1141 and the second sacrificial structures 1142 are connected, they can be removed at one time. After the removal process, multiple interposers 10 (and various components thereon) can be separated from remainder of the interposer wafer (e.g., the portions of the interposer wafer beyond the sacrificial layer removal windows 136 and the first substrate 108). At this stage, multiple interposers 10 (and various components thereon) remain connected through the protective layer 146 on the carrier substrate 148.

In some embodiments in which the sacrificial layer 106, the first sacrificial structures 1141 and the second sacrificial structures 1142 adopt silicon oxide materials, the wet etch process may use a buffered hydrofluoric acid (HF) solution or buffered oxide etch solution (buffered oxide etchant, BOE) as the etchant 150. In some embodiments in which the sacrificial layer 106, the first sacrificial structures 1141 and the second sacrificial structures 1142 adopt silicon nitride materials, the wet etch process may use a phosphoric acid solution as the etchant 150. Other suitable etchants are possible.

In some embodiments, as shown in FIG. 14, during the sacrificial layer removal process (wet etch process) the etchant 150 also removes the liner 117 of the TSVs 120 located at the lower surface 110B of the interposer substrate 110, exposing the conductive material 118 of the TSVs 120. In other embodiments, if necessary, additional etchant can be used to remove the liner 117 of the TSVs 120 at the lower surface 110B after the sacrificial layer removal process. After removing the liner 117 of the TSVs 120 at the lower surface 110B, the bottom surfaces of the TSVs 120 and the lower surface 110B of the interposer substrate 110 may be substantially coplanar, in some cases.

FIG. 15 illustrates that the resulting structure in FIG. 14 is flipped over and electrical connectors 152 are formed on the TSVs 120 exposed from the lower surface 110B of the interposer substrate 110 (of each interposer 10), in accordance with some embodiments. The electrical connectors 152 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 152 may comprise a conductive material such as solder, copper, aluminum, gold, nickel, silver, palladium, tin, the like, or a combination thereof. In some embodiments, the electrical connectors 152 are formed by initially forming a layer of solder using a suitable technique such as evaporation, electroplating, printing, solder transfer, ball placement, or the like. Once a layer of solder has been formed on the structure, a reflow may be performed in order to shape the material into the desired bump shapes. Other materials or techniques for forming the electrical connectors 152 may also be used. In some embodiments, conductive pads (not shown) may be formed on the exposed TSVs 120, and the electrical connectors 152 may be formed on the conductive pads, wherein the conductive pads may comprise under-bump metallizations (UBMs). In other embodiments, the conductive pads are not formed.

FIG. 16 illustrates that a (protective layer) removal process 154 is performed to remove the protective layer 146 in the gaps between adjacent interposers 10, gaps between adjacent encapsulants 144 on the interposers 10, and gaps between the encapsulants 144 and the carrier substrate 148, in accordance with some embodiments. In some embodiments, the removal process 154 includes using a suitable etchant or clean solvent to remove (e.g., etch away) the protective layer 146.

In other embodiments, the removal process 154 is performed to make the protective layer 146 lose its adhesive property. In some embodiments in which the carrier substrate 148 may include an optically transparent material and the protective layer 146 comprises a light-to-heat conversion (LTHC) material, the removal process 154 includes using irradiation through the carrier substrate 148 to make the protective layer 146 lose its adhesive property. In some embodiments in which the protective layer 146 comprises a thermally decomposable adhesive material, the removal process 154 includes using an anneal process or a laser irradiation to make the protective layer 146 lose its adhesive property.

When the protective layer 146 loses its adhesive property or the protective layer 146 is removed, individual interposers 10 (and the various components thereon) are separated and may be removed from the carrier substrate 148 using a pick-and-place tool (not shown), achieving the singulation of the interposers 10.

FIG. 17 illustrates a package component such as a chip-on-wafer (CoW) device 20 obtained through the above processes shown in FIGS. 1 to 16, in accordance with some embodiments. The CoW device 20 includes integrated circuit dies 140a-140c mounted on an interposer 10. The interposer 10 includes an interconnect structure 130 located over an interposer substrate 110 and coupled to the TSVs 120 within the interposer substrate 110.

Since the TSVs 120 are exposed from the lower surface 110B of the interposer substrate 110 through a sacrificial layer removal process (not a backside grinding process) in the embodiments of the present disclosure, the interposer substrate 110 can be relatively thin (as mentioned above). Accordingly, shorter TSVs 120 can also be achieved, which allows the resulting interposer 10 to have better electrical connection conductivity (e.g., less connection resistance).

Furthermore, since the lower surface 110B of the interposer 110 is not subjected to a grinding process to exposed the TSVs, the lower surface 110B of the interposer 110 can be very flat (for example, the roughness may be less than about 100 nm). This facilitates better formation of the electrical connectors 152 on the lower surface 110B. Similarly, since the interposers 10 are not separated by a mechanical die saw process (but by a sacrificial layer removal or etching process), the sidewalls of the interposer 10 (composed of the sidewalls of interposer substrate 10, ILD layer 122, and interconnect structure 130) can also be very flat (for example, the roughness may be less than about 10 nm). In addition, due to the ion implantation process used to from the sacrificial layer 106 (e.g., silicon oxide or nitride), it can be observed that the interposer substrate 10 has a decreasing oxygen or nitrogen ion concentration change from the lower surface 110B to the upper surface 110A after the sacrificial layer 106 has been removed, in some cases. More specifically, there may be a boundary zone (not shown) within the interposer substrate 10 adjacent to the surface originally covered by the sacrificial layer 106, wherein the boundary zone contains a silicon rich oxide/nitride layer. The further away from the boundary zone the position within the interposer substrate 10, the oxygen or nitrogen ion concentration decreases and approaches zero.

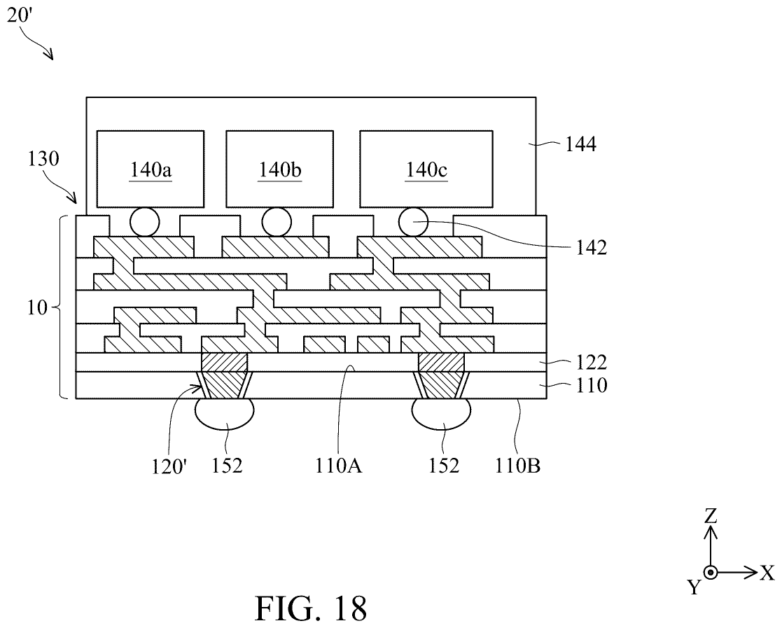

FIG. 18 illustrates a chip-on-wafer (CoW) device 20′ obtained through the above processes shown in FIGS. 1 to 16, in accordance with some embodiments. The CoW device 20′ differs from the CoW device 20 (see FIG. 17) only in that the TSVs 120 are replaced by TSVs 120′. Each TSV 120′ has sloping sidewalls instead of vertical sidewalls, with the cross-sectional area of the top of the TSV 120′ being increased. This helps the TSVs 120′ to have better electrical connection conductivity (e.g., less connection resistance).

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, while the present disclosure is described using method embodiments in which integrated circuit dies may be attached to the interposers prior to singulating the interposers, method embodiments are expressly contemplated herein in which integrated circuit dies may not be attached to the interposers prior to singulating the interposers.

Furthermore, since a die saw process is not used to separate the interposers, and the die-to-die spacing regions used to provide the sacrificial structures can be arranged arbitrarily and are not limited to being vertically staggered, the shape of the interposer die regions (which is determined by the shape of the surrounding die-to-die spacing regions or windows) may not be limited to rectangular.

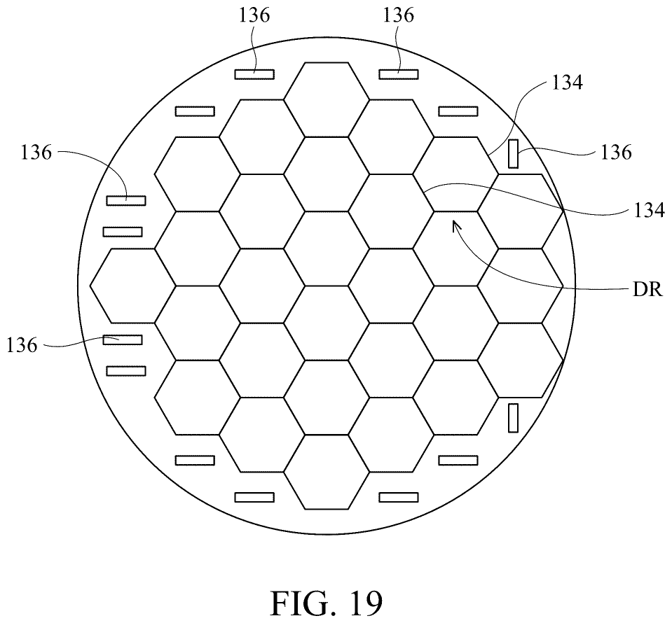

For example, FIG. 19 illustrates a plan view (e.g., top view) of an interposer wafer showing the arrangement of (interposer) die regions DR, die-to-die spacing windows 134, and sacrificial layer removal windows 136 on the interposer wafer, in accordance with some embodiments. As shown in FIG. 19, each interposer die region DR may be arranged to have a hexagonal shape rather than a rectangular shape, which helps maximize wafer area utilization. Other suitable shapes for the interposer die region DR (as well as other arrangements for the die-to-die spacing windows 134) may also be used. Moreover, the sacrificial layer removal windows 136 may also be formed in any shape and/or arrangement, depending on actual requirements. In some embodiments, only a single sacrificial layer removal window 136 may be used.

FIG. 20 illustrates a 3DIC package, such as a chip-on-wafer-on-substrate (CoWoS) package 30 that includes a CoW device (e.g., the CoW device 20 in FIG. 17) attached to a package substrate 160, in accordance with some embodiments. The CoW device 20 may be attached (e.g., bonded) to the package substrate 160 using electrical connectors 152, wherein the electrical connectors 152 may electrically connect exposed TSVs 120 on the bottom surface 110B of the interposer substrate 110 to the conductive pads (not shown) on the top surface 160A of the package substrate 160. In some embodiments, an underfill material 158 may be dispensed into the gaps between the interposer substrate 110 and the package substrate 160 to surround and protect the electrical connectors 152.

The package substrate 160 may include a suitable material, such as an organic material (e.g., a polymer and/or thermoplastic material), a semiconductor material (e.g., a semiconductor wafer, such as a silicon wafer), a ceramic material, a glass material, combinations thereof, or the like. Other suitable substrate materials are within the contemplated scope of present disclosure. A plurality of conductive interconnects (not shown) may extend through the package substrate 160 and may electrically connect conductive pads on the upper surface 160A and lower surface 160B of the package substrate 160. A plurality of solder balls 164 may be formed on the conductive pads 162 on the bottom surface 160B of the package substrate 160, and may be used to electrically connect the CoWoS package 30 to a system board (not shown) such as a printed circuit board (PCB). The solder balls 164 may include any suitable solder material, such as tin, lead, silver, indium, zinc, nickel, bismuth, antimony, cobalt, copper, germanium, alloys thereof, combinations thereof, or the like. Other suitable materials for the solder balls 164 are within the contemplated scope of disclosure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In summary, the embodiments of the present disclosure have some advantageous features. By introducing buried sacrificial layers or structures to replace interposer die saw process and backside grinding process, thinner interposer substrates and shorter TSV structures can be achieved with less damage to the interposers. Shorter TSV structures allows better electrical connection conductivity in the interposer. There are no scribe lines for the die saw process, so the wafer area utilization can be maximized. Furthermore, since the interposers are singulated using a sacrificial layer removal method, the shape of the interposers can be designed into any shape, allowing for flexible interposer geometry layout. In addition, the 3DIC fabrication methods disclosed herein can be implemented using current semiconductor processing tools and are cost-effective.

In accordance with some embodiments, a method of forming an interposer is provided. The method includes forming a wafer structure that includes a first substrate, a second substrate over the first substrate, and a sacrificial layer between the first substrate and the second substrate. The second substrate has die regions and spacing regions between the die regions. The method includes forming first sacrificial structures within the second substrate in the spacing regions. The method includes forming at least one second sacrificial structure within the second substrate and separated from the first sacrificial structures. The method includes forming conductive vias through the second substrate in the die regions. The method includes forming dielectric layers over the second substrate and forming conductive features in the dielectric layers in the die regions. The dielectric layers, the conductive features, the second substrate, and the conductive vias in each die region form an interposer. The method includes forming first windows through the dielectric layers in the spacing regions and extending to the first sacrificial structures. The method includes forming at least one second window through the dielectric layers and extending to the at least one second sacrificial structure. The method includes forming a protective layer over the dielectric layers in the die regions and filling the first windows. The method includes attaching a carrier substrate to the protective layer. The method includes removing the sacrificial layer, the first sacrificial structures and the at least one second sacrificial structure by flowing an etchant through the at least one second window into the wafer structure. The method includes removing the protective layer to separate the interposers. The method includes detaching the carrier substrate.

In accordance with some embodiments, a method of forming a package component is provided. The method includes forming a wafer structure that includes a first substrate, a second substrate over the first substrate, and a sacrificial layer between the first substrate and the second substrate. The second substrate has die regions and spacing regions between the die regions. The method includes forming first sacrificial structures within the second substrate in the spacing regions. The method includes forming at least one second sacrificial structure within the second substrate and separated from the first sacrificial structures. The method includes forming conductive vias through the second substrate in the die regions. The method includes forming dielectric layers over the second substrate and forming conductive features in the dielectric layers in the die regions. The dielectric layers, the conductive features, the second substrate, and the conductive vias in each die region form an interposer. The method includes first windows through the dielectric layers in the spacing regions to expose the first sacrificial structures. The method includes forming at least one second window through the dielectric layers to expose the at least one second sacrificial structure. The method includes bonding integrated circuit dies to the interposer in each die region. The method includes forming a protective layer over the interposers and the integrated circuit dies in the die regions and filling the first windows. The method includes attaching a carrier substrate to the protective layer. The method includes removing the sacrificial layer, the first sacrificial structures and the at least one second sacrificial structure by flowing an etchant through the at least one second window into the wafer structure, such that the interposers and the integrated circuit dies above the interposers are separated from remainder of the wafer structure. The method includes removing the protective layer. The method includes detaching the carrier substrate.

In accordance with some embodiments, an interposer is provided. The interposer includes a substrate having an upper surface and a lower surface opposite the upper surface. The interposer includes conductive vias extending through the upper surface and the lower surface of the substrate. The interposer includes an interconnect structure located over the upper surface of the substrate and the conductive vias. The concentration of oxygen or nitrogen ions within the substrate decreases from the lower surface to the upper surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an interposer, comprising:
forming a wafer structure comprising a first substrate, a second substrate over the first substrate, and a sacrificial layer between the first substrate and the second substrate,
wherein the second substrate has die regions and spacing regions between the die regions;
forming first sacrificial structures within the second substrate in the spacing regions;
forming at least one second sacrificial structure within the second substrate and separated from the first sacrificial structures;
forming conductive vias through the second substrate in the die regions;
forming dielectric layers over the second substrate and forming conductive features in the dielectric layers in the die regions,
wherein the dielectric layers, the conductive features, the second substrate, and the conductive vias in each of the die regions form an interposer;
forming first windows through the dielectric layers in the spacing regions and extending to the first sacrificial structures;
forming at least one second window through the dielectric layers and extending to the at least one second sacrificial structure;
forming a protective layer over the dielectric layers in the die regions and filling the first windows;
attaching a carrier substrate to the protective layer;
removing the sacrificial layer, the first sacrificial structures and the at least one second sacrificial structure by flowing an etchant through the at least one second window into the wafer structure;
removing the protective layer to separate the interposers; and
detaching the carrier substrate.

2. The method as claimed in claim 1, wherein the sacrificial layer, the first sacrificial structures and the at least one second sacrificial structure comprise dielectric materials.

3. The method as claimed in claim 1, wherein the sacrificial layer extends horizontally across the entire wafer structure, and
wherein the first sacrificial structures and the at least one second sacrificial structure are connected to the sacrificial layer.

4. The method as claimed in claim 1, wherein forming the wafer structure comprises:
obtaining a silicon substrate;
forming a buried dielectric in the silicon substrate through an implantation process; and
converting the buried dielectric into the sacrificial layer through an annealing process,
wherein a portion of the silicon substrate below the sacrificial layer forms the first substrate and a portion of the silicon substrate above the sacrificial layer forms the second substrate.

5. The method as claimed in claim 4, further comprising forming an epitaxy layer on a top surface of the silicon substrate to increase a thickness of the second substrate.

6. The method as claimed in claim 1, wherein the second substrate has a lower surface contacting the sacrificial layer and an upper surface opposite the lower surface,
wherein forming the conductive vias comprises forming the conductive vias through the upper surface and the lower surface of the second substrate, and
wherein after removing the sacrificial layer, the first sacrificial structures and the at least one second sacrificial structure, the conductive vias of the interposers are exposed from the lower surface.

7. The method as claimed in claim 6, further comprising forming electrical connectors on the exposed conductive vias.

8. The method as claimed in claim 6, wherein the conductive vias are formed to have sloping sidewalls, and
wherein a cross-sectional area of each of the conductive vias at the upper surface of the second substrate is greater than a cross-sectional area at the lower surface of the second substrate.

9. The method as claimed in claim 1, wherein after removing the sacrificial layer, the first sacrificial structures and the at least one second sacrificial structure, the interposers remain connected through the protective layer on the carrier substrate.

10. The method as claimed in claim 1, wherein the protective layer comprises a material having etching selectivity with materials of the sacrificial layer, the first sacrificial structures and the at least one second sacrificial structure.

11. The method as claimed in claim 1, wherein the first windows and the at least one second window are formed in a same etching step.

12. The method as claimed in claim 1, wherein each of the die regions bounded by the spacing regions has a rectangular shape or a hexagonal shape in a plan view.

13. The method as claimed in claim 12, wherein in the plan view, a pattern of the first windows correspond to a pattern of the spacing regions.

14. A method of forming a package component, comprising:
providing a wafer structure comprising a first substrate, a second substrate over the first substrate, and a sacrificial layer between the first substrate and the second substrate,
wherein the second substrate has die regions and spacing regions between the die regions;
forming first sacrificial structures within the second substrate in the spacing regions;
forming at least one second sacrificial structure within the second substrate and separated from the first sacrificial structures;
forming conductive vias through the second substrate in the die regions;
forming dielectric layers over the second substrate and forming conductive features in the dielectric layers in the die regions,
wherein the dielectric layers, the conductive features, the second substrate, and the conductive vias in each of the die regions form an interposer;
forming first windows through the dielectric layers in the spacing regions to expose the first sacrificial structures;
forming at least one second window through the dielectric layers to expose the at least one second sacrificial structure;
bonding integrated circuit dies to the interposer in each of the die regions;
forming a protective layer over the interposers and the integrated circuit dies in the die regions and filling the first windows;
attaching a carrier substrate to the protective layer;
removing the sacrificial layer, the first sacrificial structures and the at least one second sacrificial structure by flowing an etchant through the at least one second window into the wafer structure, such that the interposers and the integrated circuit dies above the interposers are separated from remainder of the wafer structure;
removing the protective layer; and
detaching the carrier substrate.

15. The method as claimed in claim 14, wherein after removing the sacrificial layer, the first sacrificial structures and the at least one second sacrificial structure, the conductive vias of the interposers are exposed from a lower surface of the second substrate, and the method further comprises:
forming electrical connectors on the exposed conductive vias.

16. The method as claimed in claim 14, further comprising molding the integrated circuit dies through an encapsulant in each of the die regions.

17. The method as claimed in claim 14, wherein the at least one second window is arranged adjacent to edges of the wafer structure, and
wherein after the protective layer is formed, the at least one second window is exposed.

18. An interposer, comprising:
a substrate having an upper surface and a lower surface opposite the upper surface;
conductive vias extending through the upper surface and the lower surface of the substrate; and
an interconnect structure located over the upper surface of the substrate and the conductive vias,
wherein a concentration of oxygen or nitrogen ions within the substrate decreases from the lower surface to the upper surface of the substrate.

19. The interposer as claimed in claim 18, wherein the lower surface of the substrate has a roughness of less than 10 nanometers.

20. The interposer as claimed in claim 18, wherein the interposer has a sidewalls composed of sidewalls of the substrate and sidewalls of the interconnect structure, and the sidewalls of the interposer have a roughness of less than 10 nanometers.
